(19) United States
(12) Patent Application Publication
(10) Pub. No.: US 2025/0362539 A1
(43) Pub. Date: Nov. 27, 2025

(54) DISPLAY SYSTEM

(71) Applicant: Japan Display Inc., Tokyo (JP)

(72) Inventors: Masato YOSHIDA, Tokyo (JP); Hirofumi OHIRA, Tokyo (JP)

(21) Appl. No.: 19/209,139

(22) Filed: May 15, 2025

(30) Foreign Application Priority Data
May 21, 2024 (JP) 2024-082879

(51) Int. Cl. G02F 1/1335; G02F 1/1333

(52) U.S. Cl. CPC G02F 1/133512; G02F 1/133311

(57) ABSTRACT

According to an aspect, a display system includes: a display device comprising a plurality of pixels arranged in a matrix with a row-column configuration on a substrate; and a surface layer covering the display device and having a semi-transmissive layer and a plurality of openings formed in the semi-transmissive layer. The pixels include a pixel provided overlapping the semi-transmissive layer and a pixel provided overlapping the opening.

### CROSS-REFERENCE TO RELATED APPLICATION

This application claims the benefit of priority from Japanese Patent Application No. 2024-082879 filed on May 21, 2024, the entire contents of which are incorporated herein by reference.

### BACKGROUND

### 1. Technical Field

What is disclosed herein relates to a display system.

### 2. Description of the Related Art

In recent years, widely known are operation display panel-equipped products with a touch sensor, in which a veneer made from natural wood or other material is disposed on the display panel (refer to WO 2019/082399 and Japanese Patent Application Laid-open Publication No. 2021-39281 (JP-A-2021-39281), for example). In WO 2019/082399, the veneer is positioned on the outer surface of the operation display panel-equipped product, and an array of LED light sources is positioned in the product. Characters and patterns composed of light emitted from the array of LED light sources can be visually recognized through the veneer.

In JP-A-2021-39281, a plurality of inorganic light emitters are provided overlapping respective transmissive parts provided in a surface layer. Therefore, when the inorganic light emitter of the display device is turned on, light from the inorganic light emitter passes through the transmissive part that is provided on the upper side of the inorganic light emitter to face the inorganic light emitter, and is output toward the outside of the display device.

In the operation display panel-equipped product disclosed in WO 2019/082399, a display image of the characters and patterns composed of light from the LED light sources that can be visually recognized through the veneer may have a reduced resolution in the display state, resulting in a blurred display image. As a result, the display image of the characters and patterns according to WO 2019/082399 is used only as an image with poor resolution that simply represents and transmits the lighting state of the LEDs as dots.

In JP-A-2021-39281, the light from the LED light sources can be output to the outside through the transmissive parts, whereby the display image can be clearly recognized, as compared with WO 2019/082399. In the technology disclosed in JP-A-2021-39281, however, it is necessary to increase the number of transmissive parts to improve the resolution. Thus, the technology disclosed in JP-A-2021-39281 is required to improve the contrast of the display image against the pattern on the surface of the veneer while reducing the number of transmissive parts.

For the foregoing reasons, there is a need for a display system that can enhance the visibility of a display image and improve the contrast of the display image.

### SUMMARY

According to an aspect, a display system includes: a display device comprising a plurality of pixels arranged in a matrix with a row-column configuration on a substrate; and a surface layer covering the display device and having a semi-transmissive layer and a plurality of openings formed in the semi-transmissive layer. The pixels include a pixel provided overlapping the semi-transmissive layer and a pixel provided overlapping the opening.

### BRIEF DESCRIPTION OF THE DRAWINGS

FIG. 1 is a schematic view of a display system according to an embodiment of the present disclosure;

FIG. 2 is a schematic plan view of a display device according to the present embodiment;

FIG. 3 is a diagram of a main configuration example of the display device according to a first embodiment;

FIG. 4 is a diagram of an example of a pixel array of a display panel according to the first embodiment;

FIG. 5 is a schematic partial sectional view of the display system according to the first embodiment;

FIG. 6 is a schematic view of the appearance of the display system when the display device does not emit light;

FIG. 7 is a schematic view of the appearance of the display system when the display device emits light;

FIG. 8 is a schematic partial sectional view of the display system according to a first modification of the first embodiment;

FIG. 9 is a schematic partial sectional view of the display system according to a second modification of the first embodiment;

FIG. 10 is a schematic partial sectional view of the display system according to a second embodiment;

FIG. 11 is a schematic partial sectional view of the display system according to a first modification of the second embodiment;

FIG. 12 is a schematic partial sectional view of the display system according to a second modification of the second embodiment;

FIG. 13 is a schematic partial sectional view of the display system according to a third embodiment; and

FIG. 14 is a schematic partial sectional view of the display system according to a modification of the third embodiment.

### DETAILED DESCRIPTION

Exemplary aspects (embodiments) to embody the invention are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the invention and easily conceivable by those skilled in the art naturally fall within the scope of the present disclosure. To make the explanation more specific, the drawings may possibly illustrate the width, the thickness, the shape, and other elements of each component more schematically than the actual aspect. These elements, however, are given by way of example only and are not intended to limit interpretation of the present disclosure. In the present specification and the drawings, components similar to those previously described with reference to previous drawings are denoted by the same reference numerals, and detailed explanation thereof may be omitted as appropriate.

In the present specification and the claims, when the term “on” is used to describe an aspect where a first structure is disposed on the upper side of a second structure, it includes both of the following cases unless otherwise noted: a case where the first structure is disposed directly on and in contact with the second structure, and a case where the first structure is disposed above the second structure with still another structure interposed therebetween.

### First Embodiment

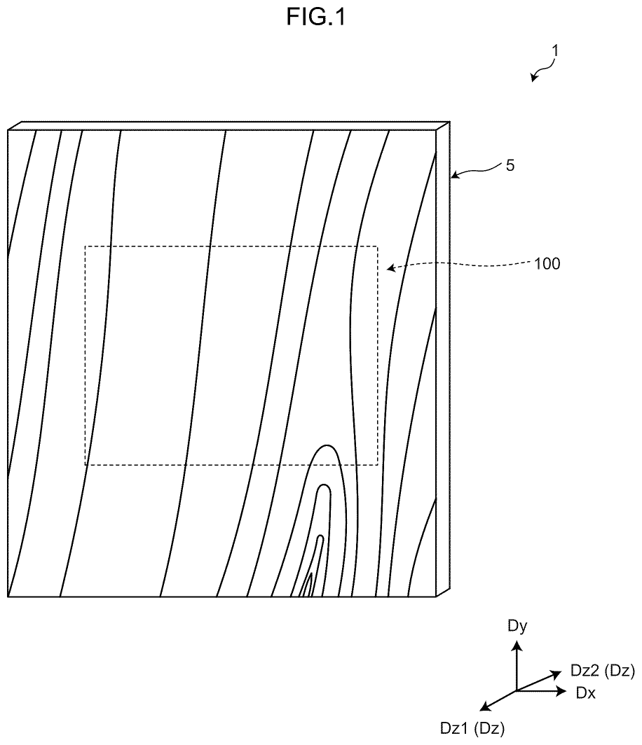

FIG. 1 is a schematic view of a display system according to an embodiment of the present disclosure. As illustrated in FIG. 1, a display system 1 according to the present embodiment includes a display device 100 and a surface layer 5. The surface layer 5 is, for example, veneer or plywood made of wood or veneer molded from wood chips, and the surface of the surface layer 5 has a wood-grain pattern, for example. Examples of the wood include, but are not limited to, sycamore wood, maple wood, cherry wood, walnut wood, etc. The thickness of the surface layer 5 ranges from 0.2 mm to 0.5 mm.

The display device 100 is attached to the surface layer 5 and displays images. The display device 100 is disposed behind the surface layer 5.

In the following description, one direction parallel to the surface of the surface layer 5 is referred to as a first direction Dx, and the other direction parallel to the surface is referred to as a second direction Dy. While the first direction Dx is orthogonal to the second direction Dy, it may intersect the second direction Dy without being orthogonal thereto. The direction orthogonal to the first direction Dx and the second direction Dy, that is, the direction orthogonal to the surface of the surface layer 5 is referred to as a third direction Dz. The third direction Dz corresponds to the normal direction of a first substrate 71, which will be described later, for example. In the following description, plan view refers to the positional relation when viewed in the third direction Dz. One of the directions parallel to the third direction Dz is referred to as a direction Dz1, and the other of the directions parallel to the third direction Dz, that is, the direction opposite to the direction Dz1 is referred to as a direction Dz2. The direction Dz1 is a direction from an array substrate SUB1, which will be described later, to the surface of the surface layer 5.

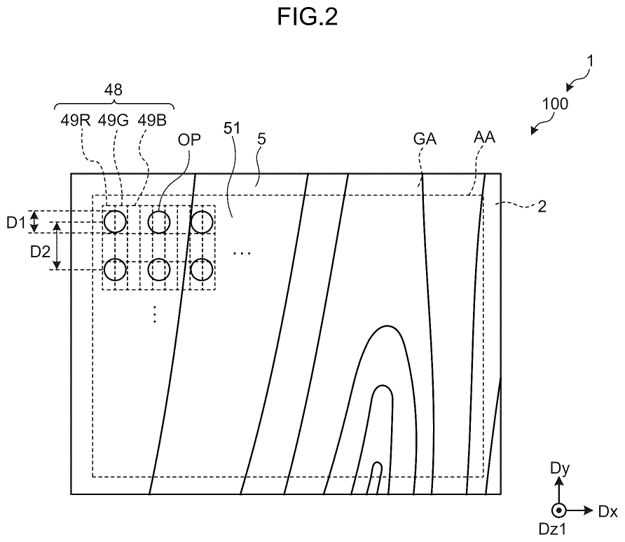

FIG. 2 is a schematic plan view of the display device according to the present embodiment. As illustrated in FIG. 2, the display device 100 includes a display panel 2.

As illustrated in FIG. 2, the display device 100 has a display region AA and a peripheral region GA. The display region AA is a region provided with a plurality of pixels 48 and a region for displaying images. The peripheral region GA is a region not overlapping the pixels 48 and is positioned outside the display region AA. The pixels 48 are arrayed in a matrix with a row-column configuration, for example, in the first direction Dx and the second direction Dy in the display region AA.

The pixels 48 each include a first sub-pixel 49R, a second sub-pixel 49G, and a third sub-pixel 49B, for example. The first sub-pixel 49R displays a first primary color (e.g., red). The second sub-pixel 49G displays a second primary color (e.g., green). The third sub-pixel 49B displays a third primary color (e.g., blue).

The first sub-pixel 49R, the second sub-pixel 49G, and the third sub-pixel 49B are arranged in this order along the first direction Dx and the second direction Dy. The array of the first sub-pixel 49R, the second sub-pixel 49G, and the third sub-pixel 49B is what is called a stripe array. In the following description, the first sub-pixel 49R, the second sub-pixel 49G, and the third sub-pixel 49B may be referred to simply as “sub-pixels 49” when they are described without being distinguished from one another. The array of the sub-pixels 49 is not limited to a stripe array.

The surface layer 5 is provided over the entire area of the display device 100 including the display region AA and the peripheral region GA in plan view. The surface layer 5 has a semi-transmissive layer 51 with a light-transmitting property and a plurality of openings OP formed in the semi-transmissive layer 51. The semi-transmissive layer 51 is a layer with a light transmittance of 1% to 50%, and the light transmittance according to the first embodiment is approximately 3.5%, for example.

The surface layer 5 is subjected to surface treatment by coating before being blasted. With this process, the surface roughness of the surface layer 5 can be reduced.

As illustrated in FIG. 2, the surface layer 5 has a plurality of openings OP. The opening OP according to the present embodiment is an opening (hole) formed through the surface layer 5 from the surface of the surface layer 5 in the direction Dz2 to the surface in the direction Dz1. The openings OP are spaced at predetermined intervals along the first direction Dx and the second direction Dy. At least one of the sub-pixels 49 is disposed at a position where the sub-pixel 49 partially overlaps the opening OP.

The openings OP according to the present embodiment are arranged in a square lattice in plan view. The arrangement, the number, and the like of the openings OP illustrated in FIG. 2 are given by way of example only and can be appropriately changed. The openings OP may be arranged in any one of a rhombic lattice and a rectangular lattice in plan view.

This configuration can increase the light transmittance to a transmittance of 5% to 20% and improve the visibility of a display image.

Here, the diameter of the opening OP in plan view is a diameter D1. The diameter D1 of the opening OP ranges from 50 μm to 100 μm.

With this structure, the openings OP can be easily formed and be made less likely to be visually recognized. While the diameter D1 is the diameter of the opening OP in the second direction Dy, it may be the diameter of the opening OP in the first direction Dx.

Here, the arrangement pitch between the openings OP in plan view is a pitch D2. The pitch D2 is the length between the center points of the openings OP adjacent in the second direction Dy. The pitch D2 ranges from 100 μm to 200 μm.

This structure can make the openings OP less likely to be visually recognized when a user views the surface layer 5 and improve the light transmittance. The pitch D2 may be the length between the center points of the openings OP adjacent in the first direction Dx.

Table 1 indicates the relation between the diameter of the opening OP, the aperture ratio, and the arrangement pitch between the openings OP. The aperture ratio represents the area ratio of the openings OP to the display region AA.

As indicated in Table 1, the arrangement pitch between the openings OP decreases as the aperture ratio increases. The pitch increases as the diameter of the opening OP increases.

To form the openings OP in as short a time as possible, the arrangement pitch between the openings OP is preferably wider. In this case, it is preferable that the arrangement pitch between the openings OP be 150 μm to 200 μm, and the aperture ratio be 10% to 15%.

With this configuration, the productivity of the openings OP is improved. The resolution of the display image is also improved because the light transmittance increases.

TABLE 1

| | | Aperture Ratio (%) | | | | | | |
|---|---|---|---|---|---|---|---|---|
| Pitch (μm) | | 5.0 | 7.5 | 10.0 | 12.5 | 15.0 | 17.5 | 20 |
| Diameter of | 50 | 198 | 161 | 141 | 125 | 114 | 106 | 99 |
| Opening (μm) | 60 | 237 | 194 | 168 | 150 | 137 | 127 | 119 |
| | 70 | 277 | 226 | 196 | 175 | 160 | 148 | 139 |
| | 80 | 316 | 258 | 224 | 200 | 183 | 169 | 158 |
| | 90 | 356 | 291 | 252 | 225 | 205 | 190 | 178 |
| | 100 | 396 | 323 | 280 | 250 | 228 | 211 | 198 |

Table 2 indicates the relation between the density of the openings OP and the arrangement pitch between the openings OP. The density of the openings OP is the number of openings OP per inch, and the unit of the density of the openings OP is dpi.

As indicated in Table 2, the density of the openings OP increases as the arrangement pitch between the openings OP decreases. When the density is 100 dpi or lower, the resolution of the display image is low. When the density is 250 dpi or higher, the arrangement pitch is small, and the openings OP are difficult to form. Therefore, the density of the openings OP ranges preferably from 100 dpi to 250 dpi.

This configuration can enhance the resolution of the display image and improve the visibility.

TABLE 2

| Pitch (μm) | 400 | 350 | 300 | 250 | 200 | 150 | 100 |
|---|---|---|---|---|---|---|---|
| Density of | 63 | 72 | 84 | 101 | 127 | 169 | 254 |
| Openings (dpi) | | | | | | | |

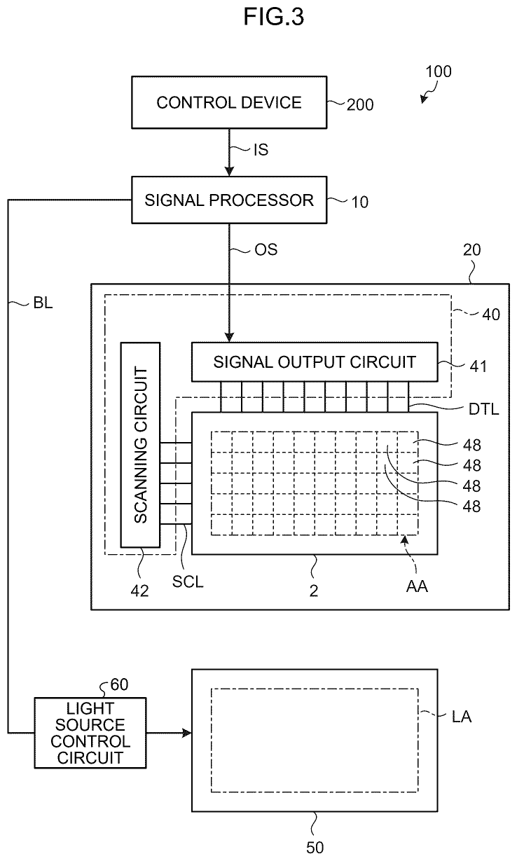

FIG. 3 is a block diagram of an exemplary configuration of the display device according to the first embodiment. As illustrated in FIG. 3, the display device 100 according to the first embodiment includes a signal processor 10, a display part 20, a light source device 50, and a light source control circuit 60. The display part 20 includes a display panel driver 40 and the display panel 2. The signal processor 10 performs various kinds of output based on input signals IS received from an external control device 200 to control the operations of the display part 20 and the light source device 50. The input signal IS is a signal serving as data for displaying an image on the display device 100 and is an RGB image signal, for example. The input signal IS corresponds to the resolution of the display panel 2. In other words, the input signal IS includes pixel signals corresponding to the number of pixels 48 and their positions in the first direction Dx and the second direction Dy in the display panel 2, which will be described later. The signal processor 10 outputs an output image signal OS generated based on the input signal IS to the display part 20. When receiving the input signal IS, the signal processor 10 outputs a light source drive signal BL for controlling the lighting of the light source device 50 to the light source control circuit 60. The light source control circuit 60 is, for example, a driver circuit for the light source device 50 and operates the light source device 50 based on the light source drive signal BL. The light source device 50 includes a light source that emits light from a light-emitting region LA. The light source control circuit 60 according to the first embodiment operates the light source device 50 such that a certain amount of light is emitted from the light-emitting region LA of the light source device 50 according to the timing of displaying a frame image.

The display part 20 includes the display panel 2 and the display panel driver 40. The display panel 2 has the display region AA provided with a plurality of pixels 48. The pixels 48 are arranged in a matrix with a row-column configuration, for example. The display panel 2 according to the first embodiment is a liquid crystal image display panel. The display panel driver 40 includes a signal output circuit 41 and a scanning circuit 42. The signal output circuit 41 is a circuit that functions as what is called a source driver and drives the pixels 48 based on the output image signal OS. The scanning circuit 42 is a circuit that functions as what is called a gate driver and outputs drive signals to scan the pixels 48 arranged in a matrix with a row-column configuration in units of a predetermined number of rows (e.g., one row). The pixel 48 is driven to output a gradation value according to the output image signal OS at the timing when the drive signal is output.

The light source device 50 is disposed behind the display part 20. The light source device 50 emits light to the display part 20 to illuminate the display part 20.

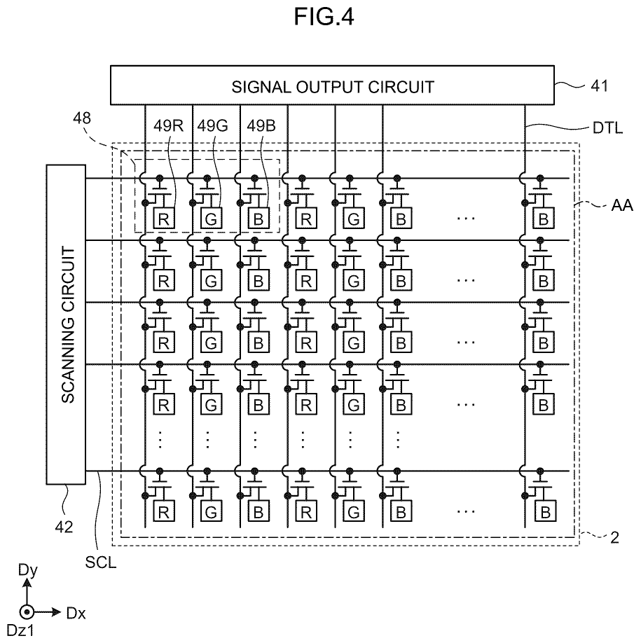

FIG. 4 is a diagram of an example of the pixel array of the display panel 2. As illustrated in FIG. 4, the pixels 48 arranged in a matrix with a row-column configuration in the display panel 2 each include the first sub-pixel 49R that displays a first color, the second sub-pixel 49G that displays a second color, and the third sub-pixel 49B that displays a third color. The first color, the second color, and the third color are not limited to the first primary color, the second primary color, and the third primary color and may be different from one another, such as complementary colors. In the following description, the first sub-pixel 49R, the second sub-pixel 49G, and the third sub-pixel 49B are referred to as sub-pixels 49 when they need not be distinguished from one another.

The pixel 48 may include another sub-pixel 49 besides the first sub-pixel 49R, the second sub-pixel 49G, and the third sub-pixel 49B. For example, the pixel 48 may include a fourth sub-pixel that displays a fourth color. The fourth sub-pixel displays the fourth color (e.g., white). When being irradiated with the same light source lighting amount, the fourth sub-pixel is preferably brighter than the first sub-pixel 49R that displays the first color, the second sub-pixel 49G that displays the second color, and the third sub-pixel 49B that displays the third color.

The display panel 2 is, for example, a transmissive color liquid crystal display panel. A first color filter that allows light in the first primary color to pass therethrough is disposed between the first sub-pixel 49R and an image observer. A second color filter that allows light in the second primary color to pass therethrough is disposed between the second sub-pixel 49G and the image observer. A third color filter that allows light in the third primary color to pass therethrough is disposed between the third sub-pixel 49B and the image observer.

The signal output circuit 41 is electrically coupled to the display panel 2 by signal lines DTL. The display panel driver 40 selects the sub-pixel 49 in the display panel 2 by the scanning circuit 42 and controls turning-on (ON) and -off (OFF) of a switching element (e.g., a thin-film transistor (TFT)) to control the operation (light transmittance) of the sub-pixel 49. The scanning circuit 42 is electrically coupled to the display panel 2 by scanning lines SCL.

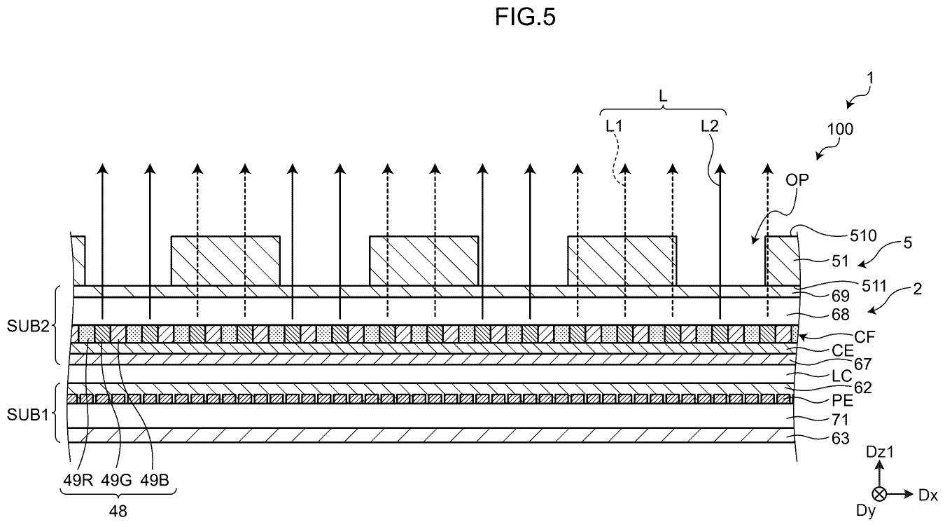

FIG. 5 is a schematic partial sectional view of the display system according to the first embodiment. As illustrated in FIG. 5, the display device 100 includes an array substrate SUB1, a counter substrate SUB2, and a liquid crystal layer LC. The surface layer 5 has a first surface 510 and a second surface 511 opposite to the first surface 510. The openings OP are formed to penetrate the surface layer 5 from the second surface 511 to the first surface 510.

The array substrate SUB1 includes a first substrate 71, a first orientation film 62, a plurality of pixel electrodes PE, and a first polarizing plate 63. The first substrate 71 is a light-transmitting substrate made of glass or the like. The first orientation film 62 is stacked on the liquid crystal layer LC side of the first substrate 71. The pixel electrodes PE are covered by the first orientation film 62. The first polarizing plate 63 is stacked on the opposite side to the liquid crystal layer LC side of the first substrate 71. The first orientation film 62 orients the liquid crystal molecules in the liquid crystal layer LC in a predetermined direction and is in direct contact with the liquid crystal layer LC. The first orientation film 62 is made of polyimide, for example, and is subjected to rubbing and/or photo-orientation treatment. The first polarizing plate 63 has the function of converting light incident from the light source device 50 disposed on the back side of the display device 100 into linearly polarized light.

The counter substrate SUB2 includes a second substrate 68, a color filter CF, a second orientation film 67, a common electrode CE, and a second polarizing plate 69. The second substrate 68 is a light-transmitting insulating substrate made of glass or the like. The color filter CF is formed on the liquid crystal layer LC side of the second substrate 68. The second orientation film 67 is formed on the liquid crystal layer LC side of the color filter CF. The common electrode CE is covered by the second orientation film 67. The second polarizing plate 69 is formed on the opposite side to the liquid crystal layer LC side of the second substrate 68.

The common electrode CE is disposed across two pixel electrodes PE adjacent to each other. Each of the pixel electrodes PE overlaps the color filter CF. The pixel electrode PE and the common electrode CE have a light-transmitting property.

The color filter CF is configured such that, for example, the first sub-pixel 49R, the second sub-pixel 49G, and the third sub-pixel 49B are periodically arrayed. Each pixel 48 includes three sub-pixels 49 and corresponds to a set of three color regions of 49R, 49G, and 49B. The color filter CF may include color regions of four or more colors. In this case, the pixel 48 may include four or more sub-pixels 49.

The display device 100 may be provided with a cover member formed of a glass substrate or a resin substrate and a detection device, such as a touch panel, if necessary.

The pixels 48 include the pixel 48 provided overlapping the semi-transmissive layer 51 and the pixel 48 provided overlapping the opening OP.

Light L transmitted through the pixel 48 includes first light L1 and second light L2. The first light L1 is light passing through the semi-transmissive layer 51 and the pixel 48 provided overlapping the semi-transmissive layer 51. The second light L2 is light passing through the opening OP and the pixel 48 provided overlapping the opening OP. This configuration enables the user to visually recognize the first light L1 and the second light L2 in a composite manner.

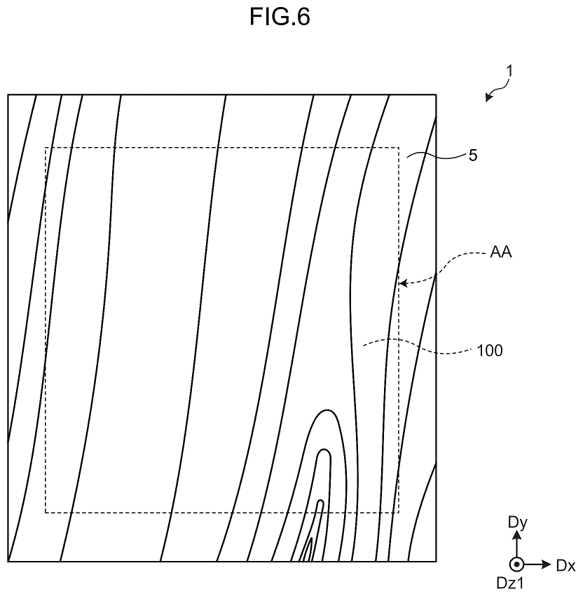

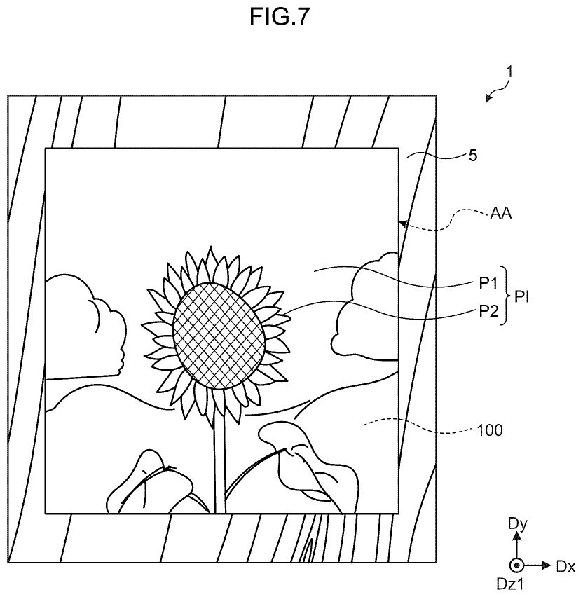

Next, how the display system 1 looks when viewed is described. FIG. 6 is a schematic view of the appearance of the display system when the display device does not emit light, and FIG. 7 is a schematic view of the appearance of the display system when the display device emits light.

As illustrated in FIG. 6, when the display device 100 does not emit light to the surface layer 5, the pixels 48 do not emit light. Therefore, if the user views the display system 1 in plan view when the display device 100 does not emit light, the surface layer 5 of the display system 1 is visually recognized by the user, and the display device 100 (display panel 2) is not visually recognized.

The openings OP in the surface layer 5 are sufficiently small and less likely to be visually recognized. Therefore, the openings OP are not visually recognized by the user.

Light from the light source device 50 reaches the user through the sub-pixels 49. As illustrated in FIG. 7, the user visually recognizes the light emitted from the light source device 50 and passing through the display panel 2, whereby the user visually recognizes an image output by the display panel 2.

When the display device 100 emits light to the surface layer 5, the light transmitted through the pixels 48 passes through the openings OP and the semi-transmissive layer 51 facing the pixels 48 in the direction Dz1 and is emitted to the outside of the display device 100.

The display panel 2 displays a display image PI on the surface of the surface layer 5 in the direction Dz1 by the first light L1 transmitted through the semi-transmissive layer 51 and the second light L2 transmitted through the opening OP. The display image PI includes a background image P1 and a picture image P2.

This configuration can improve the contrast of the display image PI against the pattern, such as a wood-grain pattern, on the surface of the surface layer 5 without increasing the number of openings OP. Therefore, the visibility of the display image is enhanced. For example, the user can more readily recognize the background image P1 against the pattern, such as a wood-grain pattern, on the surface of the surface layer 5 and can visually recognize the picture image P2 more clearly in contrast with the background image P1.

### First Modification of First Embodiment

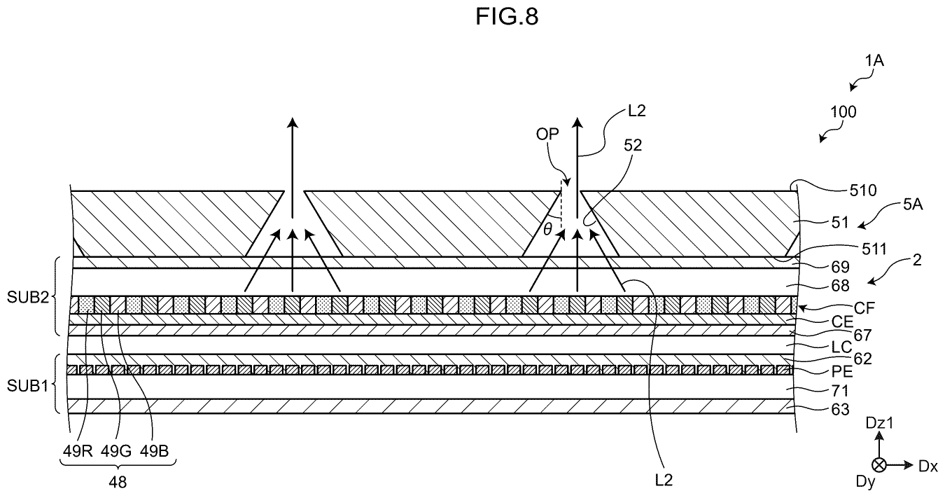

FIG. 8 is a schematic partial sectional view of the display system according to a first modification of the first embodiment. In the following description, the same components as those described in the embodiment above are denoted by the same reference numerals, and duplicate explanation thereof is omitted.

As illustrated in FIG. 8, a display system 1A according to the first modification of the first embodiment includes the display device 100 and a surface layer 5A. The surface layer 5A has a plurality of openings OP, and the shape of the opening OP is tapered in sectional view. The diameter of the opening OP on the first surface 510 is 50 μm, and the diameter of the opening OP on the second surface 511 is 100 μm.

When the thickness of the surface layer 5A is 0.2 mm, the angle θ between the vertical direction of the display device 100 and a side surface 52 of the opening OP is 14.0°.

When the thickness of the surface layer 5A is 0.3 mm, the angle θ between the vertical direction of the display device 100 and the side surface 52 of the opening OP is 9.5°.

When the thickness of the surface layer 5A is 0.4 mm, the angle θ between the vertical direction of the display device 100 and the side surface 52 of the opening OP is 7.1°.

When the thickness of the surface layer 5A is 0.5 mm, the angle θ between the vertical direction of the display device 100 and the side surface 52 of the opening OP is 5.7°.

Thus, the maximum value of the angle θ between the vertical direction of the display device 100 and the side surface 52 of the opening OP is 14°.

With this configuration, the second light L2 entering through the wide opening on the second surface 511 of the opening OP exits through the narrow opening on the first surface 510 of the opening OP, thereby improving the luminance.

### Second Modification of First Embodiment

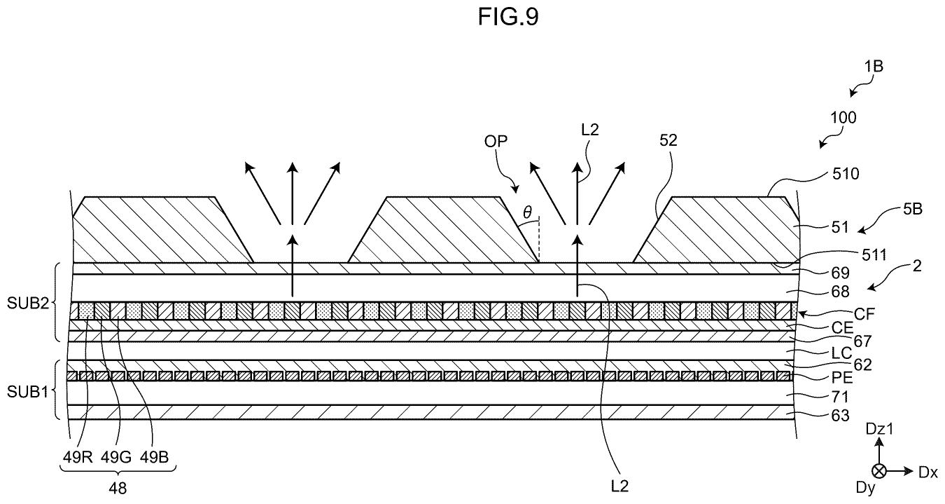

FIG. 9 is a schematic partial sectional view of the display system according to a second modification of the first embodiment. In the following description, the same components as those described in the embodiment above are denoted by the same reference numerals, and duplicate explanation thereof is omitted.

As illustrated in FIG. 9, a display system 1B according to the second modification of the first embodiment includes the display device 100 and a surface layer 5B. The surface layer 5B has a plurality of openings OP, and the shape of the opening OP is inversely tapered in sectional view. The diameter of the opening OP on the first surface 510 is 100 μm, and the diameter of the opening OP on the second surface 511 is 50 μm.

When the thickness of the surface layer 5B is 0.2 mm, the angle θ between the vertical direction of the display device 100 and the side surface 52 of the opening OP is 14.0°.

When the thickness of the surface layer 5B is 0.3 mm, the angle θ between the vertical direction of the display device 100 and the side surface 52 of the opening OP is 9.5°.

When the thickness of the surface layer 5B is 0.4 mm, the angle θ between the vertical direction of the display device 100 and the side surface 52 of the opening OP is 7.1°.

When the thickness of the surface layer 5B is 0.5 mm, the angle θ between the vertical direction of the display device 100 and the side surface 52 of the opening OP is 5.7°.

Thus, the maximum value of the angle θ between the vertical direction of the display device 100 and the side surface 52 of the opening OP is 14°.

With this configuration, the second light L2 entering through the narrow opening on the second surface 511 of the opening OP exits through the wide opening on the first surface 510 of the opening OP. As a result, the display image is made brighter overall, and the visibility of the display image is improved.

### Second Embodiment

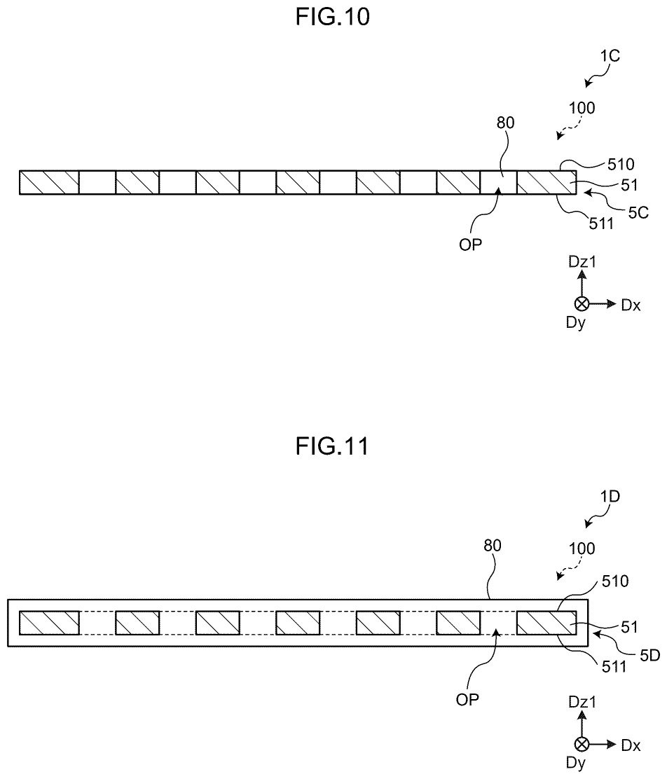

FIG. 10 is a schematic partial sectional view of the display system according to a second embodiment. In the following description, the same components as those described in the embodiment above are denoted by the same reference numerals, and duplicate explanation thereof is omitted.

As illustrated in FIG. 10, a display system 1C according to the second embodiment includes the display device 100 and a surface layer 5C. The surface layer 5C further includes a protective film 80 protecting the openings OP.

The protective film 80 is made of light-transmitting resin. Each of the openings OP is filled with the protective film 80.

With this configuration, the surface roughness of the surface layer 5C is reduced, thereby improving the feel of the surface layer 5C.

### First Modification of Second Embodiment

FIG. 11 is a schematic partial sectional view of the display system according to a first modification of the second embodiment. In the following description, the same components as those described in the embodiment above are denoted by the same reference numerals, and duplicate explanation thereof is omitted.

As illustrated in FIG. 11, a display system 1D according to the first modification of the second embodiment includes the display device 100 and a surface layer 5D. The surface layer 5D further includes a protective film 80 protecting the openings OP. The openings OP are filled with the protective film 80, and the outer peripheral surface of the surface layer 5D is covered by the protective film 80.

With this configuration, the entire surface of the surface layer 5D can be protected, thereby improving the strength of the surface layer 5D.

The protective film 80 may contain an antistatic additive. In this case, an antistatic property is improved, and generation of static electricity can be suppressed.

### Second Modification of Second Embodiment

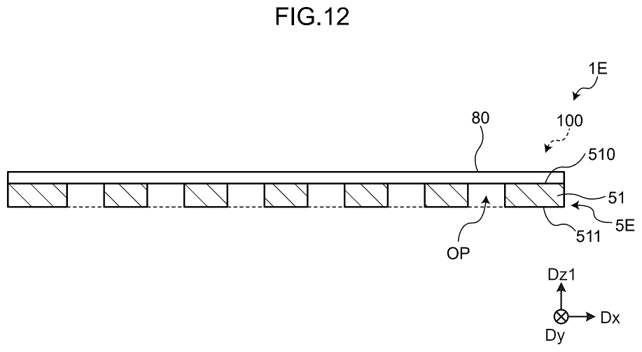

FIG. 12 is a schematic partial sectional view of the display system according to a second modification of the second embodiment. In the following description, the same components as those described in the embodiment above are denoted by the same reference numerals, and duplicate explanation thereof is omitted.

As illustrated in FIG. 12, a display system 1E according to the second modification of the second embodiment includes the display device 100 and a surface layer 5E. The surface layer 5E further includes a protective film 80 protecting the openings OP. The surface of the surface layer 5E is covered by the protective film 80.

With this configuration, the surface of the surface layer 5E can be protected, thereby improving the strength of the surface layer 5E.

### Third Embodiment

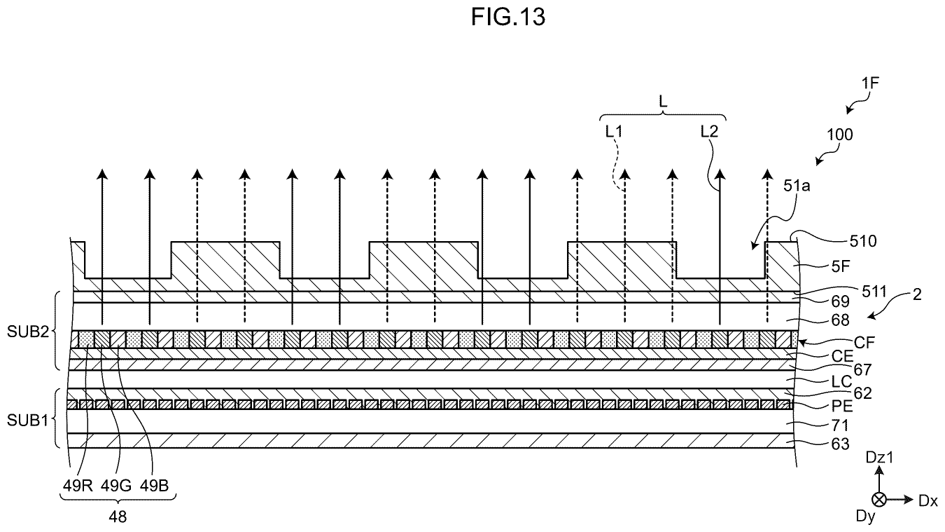

FIG. 13 is a schematic partial sectional view of the display system according to a third embodiment. In the following description, the same components as those described in the embodiments above are denoted by the same reference numerals, and duplicate explanation thereof is omitted.

As illustrated in FIG. 13, a display system 1F according to the third embodiment includes the display device 100 and a surface layer 5F. The pixels 48 include the pixel 48 provided overlapping a recess 51a and the pixel 48 provided overlapping a portion of the semi-transmissive layer 51 where no recess 51a is provided. The surface layer 5F has a plurality of recesses 51a recessed from the first surface 510 toward the second surface 511.

The light transmittance of the recess 51a is higher than the light transmittance of the portions around the recess 51a. The light L transmitted through the pixel 48 includes the first light L1 and the second light L2. The first light L1 is light passing through the portion of the semi-transmissive layer 51 where no recess 51a is provided and the pixel 48 provided overlapping the portion of the semi-transmissive layer 51 where no recess 51a is provided. The second light L2 is light passing through the recess 51a and the pixel 48 provided overlapping the recess 51a. This configuration enables the user to visually recognize the first light L1 and the second light L2 in a composite manner.

The actions and effects of the display system 1F according to the third embodiment are the same as those of the display system 1 according to the first embodiment, and therefore the detailed descriptions are omitted.

### Modification of Third Embodiment

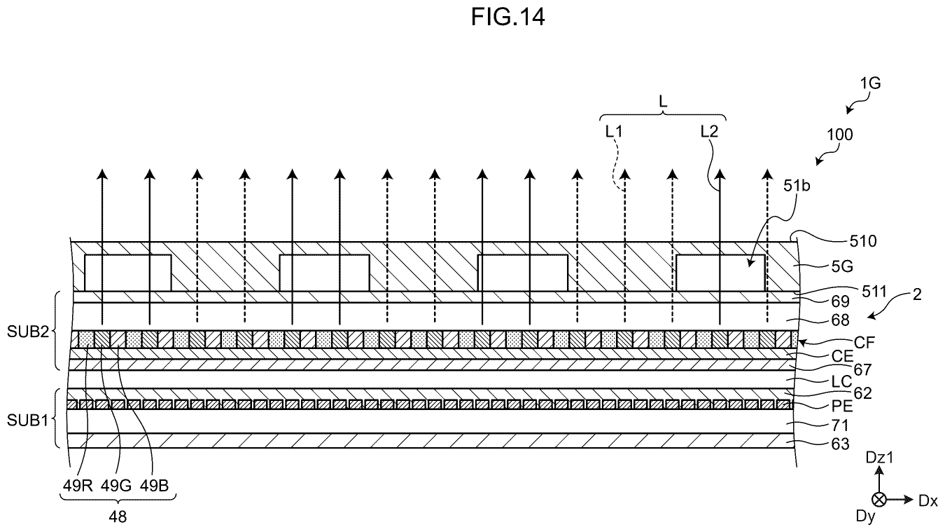

FIG. 14 is a schematic partial sectional view of the display system according to a modification of the third embodiment. In the following description, the same components as those described in the embodiments above are denoted by the same reference numerals, and duplicate explanation thereof is omitted.

As illustrated in FIG. 14, a display system 1G according to the modification of the third embodiment includes the display device 100 and a surface layer 5G. The pixels 48 include the pixel 48 provided overlapping a recess 51b and the pixel 48 provided overlapping a portion of the semi-transmissive layer 51 where no recess 51b is provided. The surface layer 5G has a plurality of recesses 51b recessed from the second surface 511 toward the first surface 510.

The light transmittance of the recess 51b is higher than the light transmittance of the portions around the recess 51b. The light L transmitted through the pixel 48 includes the first light L1 and the second light L2. The first light L1 is light passing through the portion of the semi-transmissive layer 51 where no recess 51b is provided and the pixel 48 overlapping the portion of the semi-transmissive layer 51 where no recess 51b is provided. The second light L2 is light passing through the recess 51b and the pixel 48 overlapping the recess 51b. This configuration enables the user to visually recognize the first light L1 and the second light L2 in a composite manner.

The actions and effects of the display system 1G according to the modification of the third embodiment are the same as those of the display system 1 according to the first embodiment, and therefore the detailed descriptions are omitted.

Out of other advantageous effects achieved by the aspects described in the present embodiment, advantageous effects clearly defined by the description in the present specification or appropriately conceivable by those skilled in the art are naturally achieved by the present disclosure.

What is claimed is:

1. A display system comprising:
a display device comprising a plurality of pixels arranged in a matrix with a row-column configuration on a substrate; and
a surface layer covering the display device and having a semi-transmissive layer and a plurality of openings formed in the semi-transmissive layer, wherein
the pixels include a pixel provided overlapping the semi-transmissive layer and a pixel provided overlapping the opening.

2. The display system according to claim 1, wherein the diameter of the opening ranges from 50 μm to 100 μm.

3. The display system according to claim 2, wherein an arrangement pitch between the openings ranges from 100 μm to 200 μm.

4. The display system according to claim 3, wherein resolution of the openings ranges from 100 dpi to 250 dpi.

5. The display system according to claim 4, wherein the openings are arranged in any one of a square lattice, a rhombic lattice, and a rectangular lattice in plan view.

6. The display system according to claim 5, wherein a shape of the opening is rectangular in sectional view.

7. The display system according to claim 5, wherein a shape of the opening is tapered in sectional view.

8. The display system according to claim 7, wherein a maximum value of an angle between a vertical direction of the display device and a side surface of the opening is 14 degrees.

9. The display system according to claim 6, further comprising a protective film protecting the openings, wherein
the openings are filled with the protective film.

10. The display system according to claim 9, wherein an outer peripheral surface of the surface layer is covered by the protective film.

11. The display system according to claim 6, further comprising a protective film protecting the openings, wherein
a surface of the surface layer is covered by the protective film.

12. A display system comprising:
a display device comprising a plurality of pixels arranged in a matrix with a row-column configuration on a substrate; and
a surface layer covering the display device and having a semi-transmissive layer and a plurality of recesses formed in the semi-transmissive layer, wherein
the pixels include a pixel provided overlapping the semi-transmissive layer and a pixel provided overlapping the recess.
